(19) United States
(12) Patent Application Publication
(10) Pub. No.: US 2024/0389401 A1
(43) Pub. Date: Nov. 21, 2024

(54) LIGHT EMITTING DISPLAY APPARATUS

(71) Applicant: LG Display Co., Ltd., Seoul (KR)

(72) Inventors: Daehee KIM, Paju-si (KR); MoonSoo KIM, Paju-si (KR)

(21) Appl. No.: 18/657,500

(22) Filed: May 7, 2024

(30) Foreign Application Priority Data
May 17, 2023 (KR) 10-2023-0063685

(51) Int. Cl. H10K 59/122; H10K 59/12; H10K 59/38

(52) U.S. Cl. CPC H10K 59/122; H10K 59/1201; H10K 59/38

(57) ABSTRACT

A light emitting display apparatus includes a substrate including a display area and a non-display area, a white pixel and color pixels provided in the display area, and a fluorine-based protective layer surrounding the white pixel.

### CROSS-REFERENCE TO RELATED APPLICATIONS

This application claims the benefit of the Korean Patent Application No. Oct. 10, 2023-0063685 filed on May 17, 2023, which is hereby incorporated by reference as if fully set forth herein.

### BACKGROUND

### Technical Field

The present disclosure relates to a light emitting display apparatus.

### Description of the Related Art

Light emitting display apparatuses are mounted on or provided in electronic products such as televisions, monitors, notebook computers, smart phones, tablet computers, electronic pads, wearable devices, watch phones, portable information devices, navigation devices, or vehicle control display devices, etc., to display images.

As a resolution of a light emitting display panel increases progressively, leakage current between adjacent pixels increases, and thus undesired light occurs.

Moreover, light emitting devices provided in pixels of a light emitting display panel may be affected by moisture penetrating from the outside. However, as a resolution of a light emitting display panel increases progressively, it becomes increasingly difficult to prevent moisture penetration between pixels.

### BRIEF SUMMARY

The present disclosure is directed to providing a light emitting display apparatus that, among others, substantially obviates one or more problems due to limitations and disadvantages of the related art.

An aspect of the present disclosure is directed to providing a light emitting display apparatus in which an outside of a white pixel is surrounded by a fluorine-based protective layer.

Additional technical characteristics and features of the disclosure will be set forth in part in the description which follows and in part will become apparent to those having ordinary skill in the art upon examination of the following or may be learned from practice of the disclosure. The technical characteristics and features of the disclosure may be realized and attained by the structure particularly pointed out in the written description and claims hereof as well as the appended drawings.

To achieve these and other technical characteristics and in accordance with the purpose of the disclosure, as embodied and broadly described herein, there is provided a light emitting display apparatus including a substrate including a display area and a non-display area, a white pixel and color pixels provided in the display area, and a fluorine-based protective layer surrounding the white pixel.

It is to be understood that both the foregoing general description and the following detailed description of the present disclosure are example and explanatory and are intended to provide further explanation of the disclosure.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is an example diagram illustrating a configuration of a light emitting display apparatus according to an embodiment of the present disclosure;

FIG. 2 is an example diagram illustrating a structure of a pixel applied to a light emitting display apparatus according to an embodiment of the present disclosure;

FIG. 3 is an example diagram illustrating a structure of a control driver applied to a light emitting display apparatus according to an embodiment of the present disclosure;

FIG. 4 is a plan view illustrating pixels arranged in an area A of FIG. 1;

FIG. 5 is another plan view illustrating pixels arranged in an area A of FIG. 1;

FIG. 6 is an example diagram illustrating a cross-sectional surface taken along line K-K′ illustrated in FIG. 4;

FIG. 7 is an example diagram illustrating a cross-sectional surface taken along line L-L′ illustrated in FIG. 4;

FIG. 8 is another example diagram illustrating a cross-sectional surface taken along line K-K′ illustrated in FIG. 4; and

FIGS. 9A to 9E are example diagrams illustrating a method of manufacturing a light emitting display panel according to an embodiment of the present disclosure.

### DETAILED DESCRIPTION

Reference will now be made in detail to the example embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. When “comprise,” “have,” and “include” described in the present disclosure are used, another part may be added unless “only” is used. The terms of a singular form may include plural forms unless referred to the contrary.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct (ly)” is used.

In describing a time relationship, for example, when the temporal order is described as, for example, “after,” “subsequent,” “next,” and “before,” a case that is not continuous may be included unless a more limiting term, such as “just,” “immediate (ly),” or “direct (ly)” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first,” “second,” “A,” “B,” “(a),” “(b),” etc., may be used. These terms are intended to identify the corresponding elements from the other elements, and basis, order, or number of the corresponding elements should not be limited by these terms. The expression that an element is “connected,” “coupled,” or “adhered” to another element or layer the element or layer can not only be directly connected or adhered to another element or layer, but also be indirectly connected or adhered to another element or layer with one or more intervening elements or layers “disposed,” or “interposed” between the elements or layers, unless otherwise specified.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in co-dependent relationship.

Hereinafter, embodiments of the present disclosure will be described in detail with reference to the accompanying drawings.

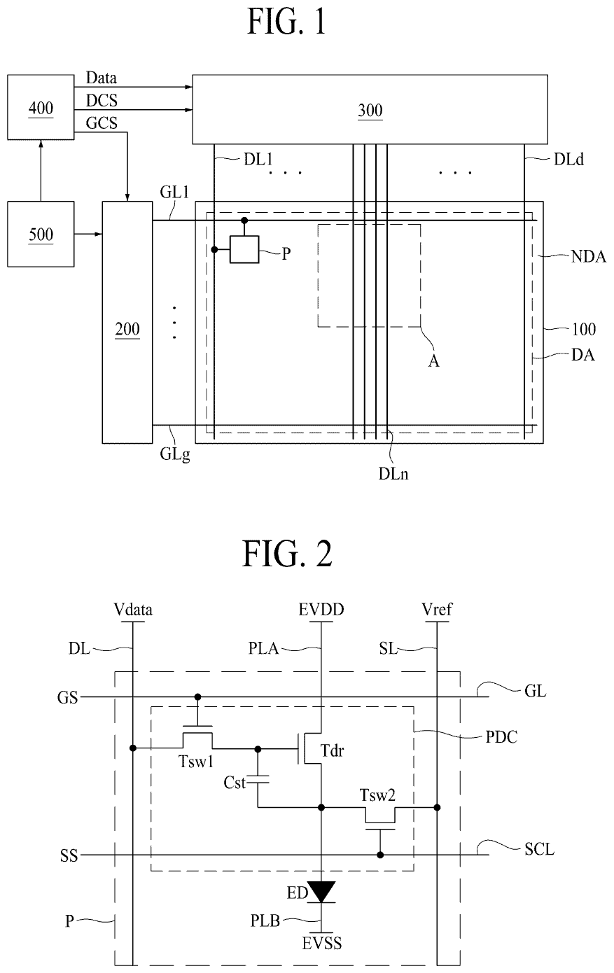

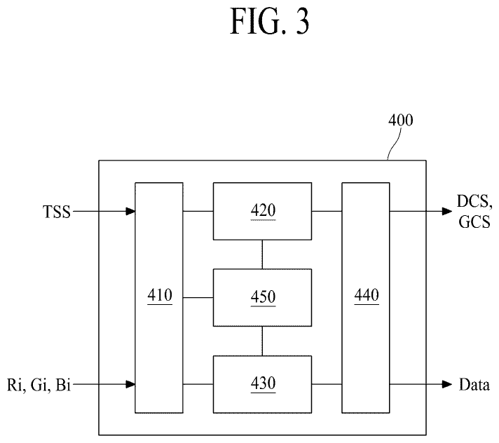

FIG. 1 is an example diagram illustrating a configuration of a light emitting display apparatus according to an embodiment of the present disclosure, FIG. 2 is an example diagram illustrating a structure of a pixel applied to a light emitting display apparatus according to an embodiment of the present disclosure, and FIG. 3 is an example diagram illustrating a structure of a control driver applied to a light emitting display apparatus according to an embodiment of the present disclosure.

A light emitting display apparatus according to an embodiment of the present disclosure can be various kinds of electronic devices or be included in various kinds of electronic devices. For example, the electronic device can be a smartphone, a tablet PC, a television, a monitor, etc., and the electronic device can be included in a smartphone, a tablet PC, a television, a monitor, etc.

The light emitting display apparatus according to an embodiment of the present disclosure, as illustrated in FIG. 1, can include a light emitting display panel 100 which includes a display area DA displaying an image and a non-display area NDA provided outside the display area DA, a gate driver 200 which supplies gate signals to a plurality of gate lines GL1 to GLg provided in the display area DA of the display panel 100, a data driver 300 which supplies data voltages Vdata to a plurality of data lines DL1 to DLd provided in the display area DA of the display panel 100, a control driver 400 which controls driving of the gate driver 200 and the data driver 300, and a power supply 500 which supplies power to the control driver 400, the gate driver 200, the data driver 300, and the light emitting display panel 100.

The light emitting display panel 100 can include a display area DA and a non-display area NDA. Gate lines GL1 to GLg, data lines DL1 to DLd, and pixels P can be provided in the display area DA. Accordingly, an image can be output in the display area DA. Here, g and d are natural numbers. The non-display area NDA can surround the outer periphery of the display area DA, and can be provided inside the display area DA. An image is not displayed in the non-display area NDA.

For example, when a camera hole is provided in the display area DA, a non-display area NDA in which an image is not displayed can be provided around the camera hole.

The pixel P included in the light emitting display panel 100, as illustrated in FIG. 2, can include a pixel driving circuit PDC which includes a switching transistor Tsw1, a storage capacitor Cst, a driving transistor Tdr, and a sensing transistor Tsw2, and a light emitting device ED connected to the pixel driving circuit PDC.

A first terminal of the driving transistor Tdr can be connected to a first voltage supply line through which a first voltage EVDD is supplied, and a second terminal of the driving transistor Tdr can be connected to the light emitting device ED.

A first terminal of the switching transistor Tsw1 can be connected to a data line DL, a second terminal of the switching transistor Tsw1 can be connected to a gate of the driving transistor Tdr, and a gate of the switching transistor Tsw1 can be connected to a gate line GL.

A data voltage Vdata can be supplied through the data line DL and a gate signal GS can be supplied through the gate line GL.

The sensing transistor Tsw2 can be provided for measuring a threshold voltage of the driving transistor Tdr or mobility of an electrical charge. A first terminal of the sensing transistor Tsw2 can be connected to the second terminal of the driving transistor Tdr and the light emitting device ED, a second terminal of the sensing transistor Tsw2 can be connected to a sensing line SL through which the reference voltage Vref is supplied, and a gate of the sensing transistor Tsw2 can be connected to a sensing control line SCL through which a sensing control signal SS is supplied.

The sensing line SL can be connected to the data driver 300 and can be connected to the power supply 500 through the data driver 300. For example, the reference voltage Vref supplied from the power supply 500 can be supplied to the pixels through the sensing line SL and sensing signals transmitted from the pixels P can be processed by the data driver 300.

The light emitting device ED can include a first electrode supplied with a first voltage EVDD through the driving transistor Tdr, a second electrode connected to a second voltage supply line PLB through which a second voltage EVSS is supplied, and a light emitting layer provided between the first electrode and the second electrode. The first electrode can be an anode and the second electrode can be a cathode.

The structure of the pixel P applied to the present disclosure is not limited to the structure illustrated in FIG. 2. Accordingly, the structure of the pixel P can be changed to various shapes.

The gate driver 200 can be configured as an integrated circuit (IC) and mounted in the non-display area NDA. Moreover, the gate driver 200 can be directly embedded into the non-display area NDA by using a gate-in panel (GIP) type. When the gate driver 200 uses the GIP type, transistors configuring the gate driver 200 can be provided in the non-display area NDA through the same process as transistors included in the pixels P of the display area DA. Moreover, the gate driver 200 can be provided in the display area DA in which light emitting devices are provided.

The gate driver 200 can supply gate pulses GP1 to GPg to the gate lines GL1 to GLg.

When a gate pulse GP generated by the gate driver 200 is supplied to a gate of the switching transistor Tsw1 included in the pixel P, the switching transistor Tsw1 can be turned on. When the switching transistor Tsw1 is turned on, data voltage Vdata supplied through a data line DL can be supplied to the pixel P.

When a gate-off signal generated by the gate driver 200 is supplied to the switching transistor Tsw1, the switching transistor Tsw1 can be turned off. When the switching transistor Tsw1 is turned off, a data voltage may not be supplied to the pixel P any longer.

The gate signal GS supplied to the gate line GL can include the gate pulse GP and the gate-off signal.

The power supply 500 can generate various powers and supply the generated powers to the control driver 400, the gate driver 200, the data driver 300, and the light emitting display panel 100.

The data driver 300 can be connected to data lines DL1 to DLd and sensing lines SL. For example, each of the sensing lines can be commonly connected to pixels included in a unit pixel capable of displaying white among pixels connected to one gate line, but can be connected to each of the pixels configuring the unit pixel.

The data driver 300 can output data voltages Vdata by using data control signals DCS and image data Data transmitted from the control driver 400.

The control driver 400 can realign input image data Ri, Gi, and Bi transmitted from an external system by using a timing synchronization signal TSS transmitted from the external system and can generate a data control signal DCS which is to be supplied to the data driver 300 and a gate control signal GCS which is to be supplied to the gate driver 200.

To this end, as illustrated in FIG. 3, the control driver 400 can include a data aligner 430 which realigns input image data Ri, Gi, and Bi to generate image data Data and supply the image data Data to the data driver 300, a control signal generator 420 which generates the gate control signal GCS and the data control signal DCS by using the timing synchronization signal TSS, a control unit 410 which transmits the timing synchronization signal TSS transmitted from the external system to the control signal generator 420 and transmits the input image data Ri, Gi, and Bi transmitted from the external system to the data aligner 430, and an output unit 440 which supplies the data driver 300 with the image data Data generated by the data aligner 430 and the data control signal DCS generated by the control signal generator 420 and supplies the gate driver 200 with the gate control signal GCS generated by the control signal generator 420.

The control signal generator 420 can generate a power control signal supplied to the power supply 500.

The control driver 400 can further include a storage unit for storing various information. The storage unit 450 can be included in the control driver 400 as illustrated in FIG. 3, but can be separated from the control driver 400 and provided independently.

The external system can perform a function of driving the control driver 400 and an electronic device. For example, when the electronic device is a television (TV), the external system can receive various kinds of sound information, image information, letter information, etc., over a communication network and can transmit the received image information to the control driver 400. In this case, the image information can be input image data Ri, Gi, and Bi.

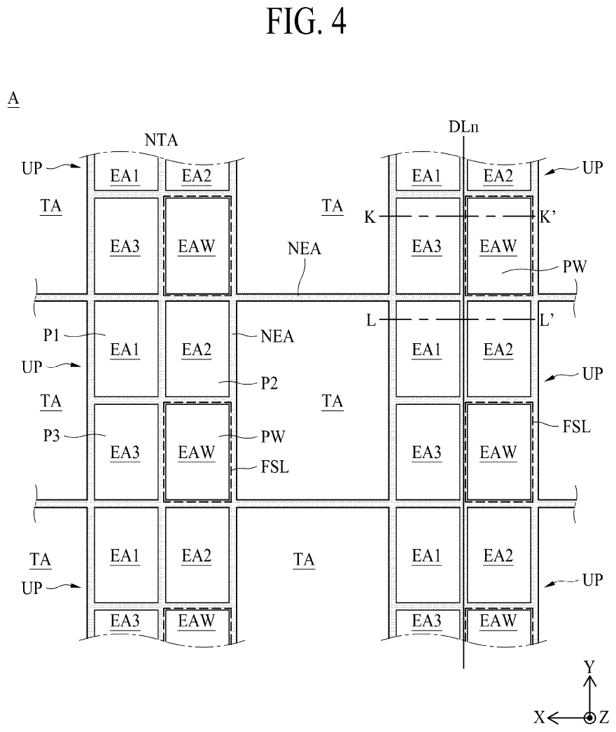

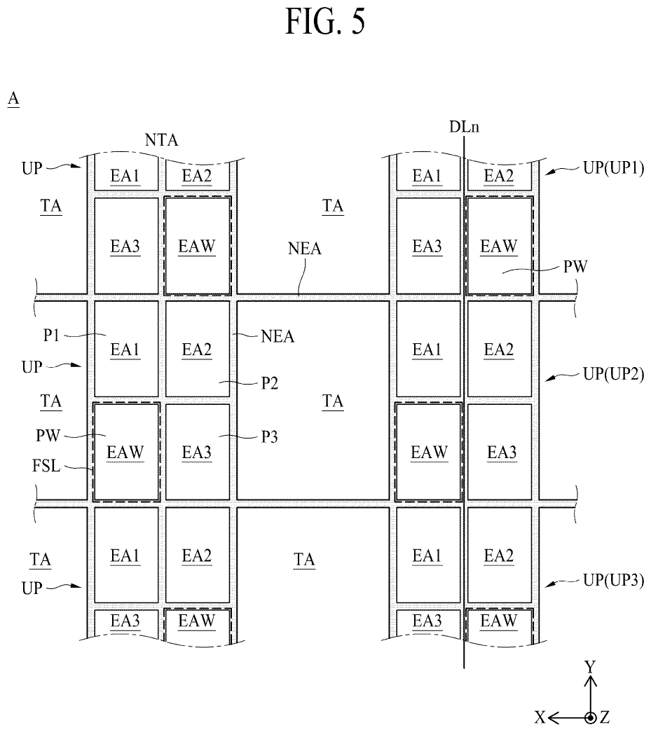

FIG. 4 is a plan view illustrating pixels arranged in an area A of FIG. 1, and FIG. 5 is another plan view illustrating pixels arranged in an area A of FIG. 1.

The present disclosure can be applied to a light emitting display panel 100 which includes a transmission area TA that is configured to allow light to transmit therethrough, and can also be applied to a light emitting display panel 100 which does not include a transmission area TA.

Hereinafter, for convenience of description, a light emitting display panel 100 including the transmission area TA will be described as an example of a light emitting display panel according to the present disclosure.

The display area DA can include a transmission area TA (or referred to as a transparent area) and a non-transmission area NTA. The transmission area TA can be an area which allows most of light incident from the outside to pass through. The non-transmission area NTA can be an area which does not transmit most of light incident from the outside. Moreover, the non-transmission area NTA can mean an area where pixels P are provided.

Due to the transmission area TA, an object or background located on the rear side of a light emitting display panel 100 can be visible from the front of the light emitting display panel 100.

The non-transmission area NTA can be disposed between adjacent transmission areas TA, and pixels P and signal lines can be disposed in the non-transmission area NTA.

Particularly, the non-transmission area NTA can include a light emission area EA in which light is emitted and a non-light emission area NEA in which light is not emitted.

Light can be emitted by a light emitting device ED in a light emission area EA of the non-transmission area NTA, and a pixel driving circuit configuring a pixel P and signal lines connected to the pixel can be provided in the non-light emission area NEA of the non-transmission area NTA.

Moreover, a bank surrounding the light emission area EA can be provided in the non-light emission area NEA.

The signal lines can include first signal lines extending in a first direction (or Y-axis direction) in the non-transmission area NTA and second signal lines extending in a second direction (or X-axis direction) different from the first direction. For example, the first signal lines can include data lines DL and sensing lines SL, and the second signal lines can include gate lines GL.

Unit pixel UP including four pixels P can be provided in the non-transmission area NTA. White light can be emitted through the unit pixel UP.

The unit pixel UP can include a first pixel P1, a second pixel P2, a third pixel P3, and a white pixel PW. The first pixel P1 can include a first light emission area EA1 which emits light of a first color, the second pixel P2 can include a second light emission area EA2 which emits light of a second color, the third pixel P3 can include a third light emission area EA3 which emits light of a third color, and the white pixel PW can include a white light emission area EAW which emits white light.

For example, the first light emission area EA1 can emit blue light, the second light emission area EA2 can emit red light, the third light emission area EA3 can emit green light, and the white light emission area EAW can emit white light.

That is, the example unit pixel UP includes a white light emission area EAW which emits white light.

The transmission area TA can be disposed between adjacent non-transmission areas NTA, and light emitting devices ED and pixel driving circuits PDC corresponding to the pixels P1, P2, P3, and PW may not be provided in the transmission area TA.

For example, non-transmission element or opaque element may not be disposed in the transmission area TA, and thus, the transmission area TA can be an area with a high light transmittance that allows light to transmit through.

For example, the transmission area TA may not overlap the pixel driving circuit PDC corresponding to the pixels P1, P2, P3, and PW. Moreover, the transmission area TA may not overlap light emitting devices corresponding to the pixels P1, P2, P3, and PW.

For example, the transmission area TA can be alternately arranged with the non-transmission area (for example, non-light emission area NEA) along the first direction (or the Y-axis direction) as illustrated in FIGS. 4 and 5, and can be alternately arranged with the non-transmission area NTA along the second direction (or X-axis direction).

As another example, the transmission area TA can be arranged to surround the non-transmission area NTA, or the non-transmission area NTA can be arranged to surround the transmission area TA.

Hereinafter, for convenience of description, each of the remaining pixels P1, P2, and P3 excluding the white pixel PW among the four pixels P1, P2, P3, and PW of the unit pixel UP is referred to as a color pixel. Particularly, when color pixels do not need to be distinguished, as a reference numeral for the color pixel, P, which is the same as the reference numeral for the pixel, can be used.

Unit pixels UP are provided in the display area DA of the light emitting display panel 100, and each of the unit pixels UP can include one white pixel PW and three color pixels P1, P2, and P3.

The color pixels P1, P2, and P3 can emit blue light, red light, and green light, as described above, but the present disclosure is not limited thereto. Accordingly, the color pixels P1, P2, and P3 can emit other combinations of color lights.

Each of the color pixels P1, P2, and P3 is provided with a color filter. The color of light emitted from each of the color pixels P1, P2, and P3 can be determined by the color of the color filter.

Because white light is emitted from the white pixel PW, a color filter is not provided in the white pixel PW.

As illustrated in FIGS. 4 and 5, a fluorine-based protective layer FSL surrounding the outside of the white pixel PW can be provided on the outside of the white pixel PW.

Particularly, the fluorine-based protective layer FSL can be provided on an upper end of the bank surrounding the outside of the white pixel PW. As described above, the bank can be provided in the non-light emission area NEA surrounding the light emission area EA.

In this case, a light emitting layer provided inside the fluorine-based protective layer FSL, e.g., that of a white pixel PA, and a light emitting layer provided outside the fluorine-based protective layer FSL, e.g., that of a color pixel P1, P2, or P3, can be separated by the fluorine-based protective layer FSL.

Even if the light emitting layer provided inside the fluorine-based protective layer FSL and the light emitting layer provided outside the fluorine-based protective layer FSL are not completely separated by the fluorine-based protective layer FSL, a length between the light emitting layer provided inside the fluorine-based protective layer FSL and the light emitting layer provided outside the fluorine-based protective layer FSL can be lengthened by the fluorine-based protective layer FSL.

Accordingly, the moisture penetration path through the light emitting layer can be blocked or lengthened.

Accordingly, moisture penetration from the color pixels P1, P2, and P3 to the white pixel PW can be prevented or reduced, and moisture penetration from the white pixel PW to the color pixels P1, P2, and P3 can be prevented or reduced.

The fluorine-based protective layer FSL can include a fluorine-based material used in the manufacturing process of a light emitting display panel 100. For example, the fluorine-based material can be a material which functions as an etch stopper for an organic layer in the process of patterning the organic layer of the light emitting display panel 100, or can be a material which functions as a pattern mask in the process of patterning the organic layer of the light emitting display panel 100.

In more detail, the fluorine-based material can be a fluoropolymer. In a fluoropolymer, carbon-carbon bonds are formed continuously in a chain structure, and the functional group of the fluoropolymer includes a large amount of fluorine (F).

Fluorine-based materials contain a large amount of fluorine (F) and thus, can have orthogonality. An orthogonality can mean a characteristic in which two objects exist independently, regardless of each other. Accordingly, fluorine-based materials can have both hydrophobic properties, which have low affinity for water, and oleophobic properties, which have low affinity for oil. Due to this orthogonality, the fluorine-based material can be separated from moisture or reject moisture. The application of fluorine-based materials can be confirmed through TOF-SIMS (Time of flight secondary ion mass spectrometer) analysis.

Therefore, as described above, moisture penetration and moisture transfer between pixels can be prevented or reduced by the fluorine-based protective layer FSL.

Moreover, the light emitting layer provided inside the fluorine-based protective layer FSL and the light emitting layer provided outside the fluorine-based protective layer FSL can be completely or partially separated by the fluorine-based protective layer FSL, and a length between the light emitting layer provided inside the fluorine-based layer FSL and the light emitting layer provided outside the fluorine-based protective layer FSL can be lengthened by the fluorine-based protective layer FSL.

Accordingly, leakage current through the light emitting layer can be reduced.

For example, the fluorine-based protective layer FSL can have a reverse taper structure, and thus, the light emitting layer formed of organic material can be cut off in the fluorine-based protective layer FSL, and thus, leakage current from the color pixel to the white pixel PW and leakage current from the white pixel PW to the color pixel can be reduced or eliminated.

Because the fluorine-based protective layer FSL has a greater resistance characteristic than the light emitting layer, when the light emitting layer is not cut off, leakage current may flow through the light emitting layer rather than the fluorine-based protective layer FSL. However, because the length of the light emitting layer provided between the color pixels and the white pixel PW is lengthened by the fluorine-based protective layer FSL, the leakage current between the color pixels and the white pixel PW can be reduced.

In this case, because the cathode provided at an upper end of the light emitting layer can be provided on the light emitting display panel by a sputter process with high step coverage, the cathode can be formed continuously along the fluorine-based protective layer FSL in a reverse taper structure.

Accordingly, the same voltage can be supplied to all pixels through the cathode.

White pixels PW can be provided in the shape illustrated in FIG. 4 or in the shape illustrated in FIG. 5. Particularly, a transmission area TA through which light transmits can be provided on at least one of outer portions of the white pixel PW.

For example, as illustrated in FIG. 4, white pixels PW are provided along the data line DL and can be provided only on one side of the data line DL. More specifically, white pixels PW provided along an nth data line DLn can be provided only on the right side of the nth data line DLn.

In this case, one of the color pixels can be provided between the white pixels PW, and a transmission area TA can be provided on the right side of the white pixels PW.

In more detail, unit pixels UP can be provided along the nth data line DLn provided on the substrate 101. Each of the unit pixels UP can include three color pixels P1, P2, and P3, and a white pixel PW. Among the three color pixels P1, P2, and P3, the first color pixel P1 and the second color pixel P2 can be arranged with the nth data line DLn interposed therebetween. Among the three color pixels, the third color pixel P3 and the white pixel PW can be arranged with the nth data line DLn interposed therebetween. For example, the third color pixel P3 can be provided on the left side of the nth data line DLn, and the white pixel PW can be provided on the right side of the nth data line DLn.

Among the three color pixels P1, P2, and P3 and the white pixel PW provided in the unit pixel UP, the fluorine-based protective layer FSL can be provided only on the outer portion of the white pixel PW.

In this case, on the left side of the first pixels P1 and the third pixels P3 provided on the left side of the nth data line DLn, a transmission area TA (for example, a first transmission area) through which light transmits can be provided. Moreover, on the right side of the second pixels P2 and the white pixels PW provided on the right side of the nth data line DLn, a transmission area TA (for example, a second transmission area) through which light transmits can be provided.

As described above, moisture penetrating through the transmission area TA adjacent to the white pixel PW cannot be transmitted to the color pixels adjacent to the white pixel PW due to the fluorine-based protective layer FSL surrounding the white pixel PW. Also, moisture penetrating into the color pixels cannot be transmitted to the white pixel PW due to the fluorine-based protective layer FSL surrounding the white pixel PW.

Moreover, between the white pixel PW and the color pixel adjacent to the white pixel PW, leakage current cannot be transmitted or can be reduced due to the fluorine-based protective layer FSL.

As another example, white pixels PW can be alternately provided on the left and right sides of the data line DL, as illustrated in FIG. 5. Particularly, a transmission area TA through which light transmits can be provided on at least one of the outer portions of the white pixel PW.

More specifically, unit pixels UP can be provided along the nth data line DLn. In this case, a white pixel PW provided in a first unit pixel UP1 among the unit pixels UP can be provided on the right side of the nth data line DLn, a white pixel PW provided in a second unit pixel UP2 among the unit pixels UP can be provided on the left side of the nth data line DLn, and a white pixel PW provided in a third unit pixel UP3 among the unit pixels UP can be provided on the right side of the nth data line DLn.

In this case, the white pixels PW can be alternately adjacent to the transmission area TA provided on the left and right sides of the unit pixels. For example, the white pixel PW provided in the first unit pixel UP1 can be adjacent to the transmission area TA provided on the right side of the first unit pixel UP1, the white pixel PW provided in the second unit pixel UP2 can be adjacent to the transmission area TA provided on the left side of the second unit pixel UP2, and the white pixel PW provided in the third unit pixel UP3 can be adjacent to the transmission area TA provided on the right side of the third unit pixel UP3.

Therefore, moisture penetrating into the white pixel PW from the transmission area TA provided on the left side of the unit pixels UP cannot be transmitted to the color pixels adjacent to the white pixel PW due to the fluorine-based protective layer FSL surrounding the white pixel PW. Moisture penetrating into the color pixels from the transmission area TA provided on the right side of the unit pixels UP also cannot be transmitted to the white pixel adjacent to the color pixels due to the fluorine-based protective layer FSL surrounding the white pixel PW.

Moreover, moisture penetrating into the white pixel PW from the transmission area TA provided on the right side of the unit pixels UP cannot be transmitted to the color pixels adjacent to the white pixel PW due to the fluorine-based protective layer FSL surrounding the white pixel PW. Moisture penetrating into the color pixels from the transmission area TA provided on the left side of the unit pixels UP also cannot be transmitted to the white pixel adjacent to the color pixels due to the fluorine-based protective layer FSL surrounding the white pixel PW.

Moreover, between the white pixel PW and the color pixel adjacent to the white pixel PW, leakage current may not be transmitted or may be reduced by the fluorine-based protective layer FSL.

Therefore, in the light emitting display apparatus according to the present disclosure, moisture transmission between the white pixel PW and the color pixels P1, P2, and P3 can be prevented or reduced, and leakage current between the color pixels P1, P2, and P3 can be reduced or prevented. Accordingly, the quality of the light emitting display apparatus can be improved.

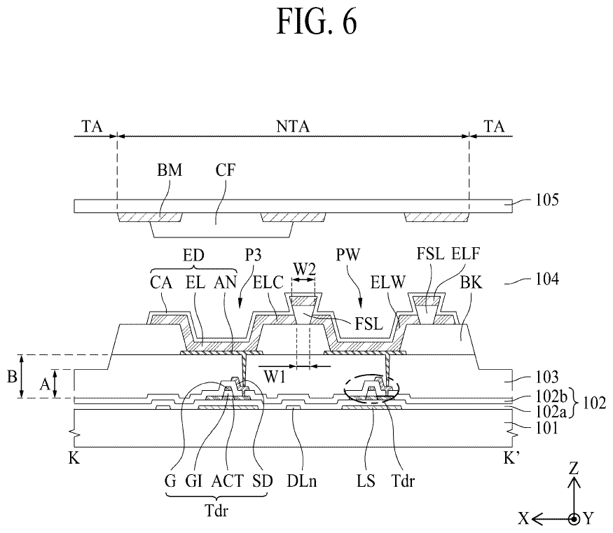

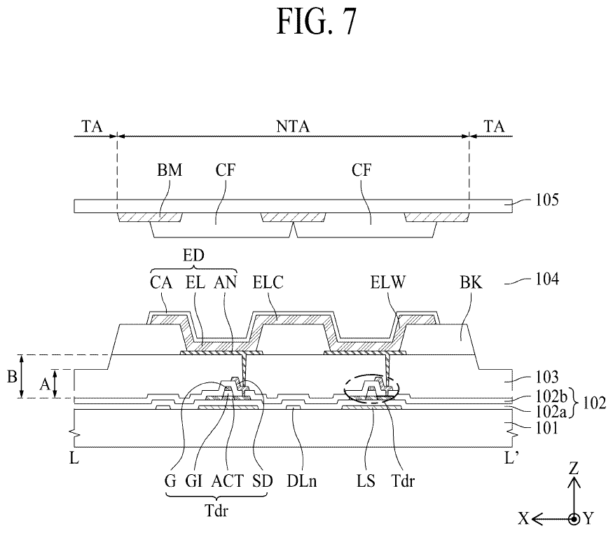

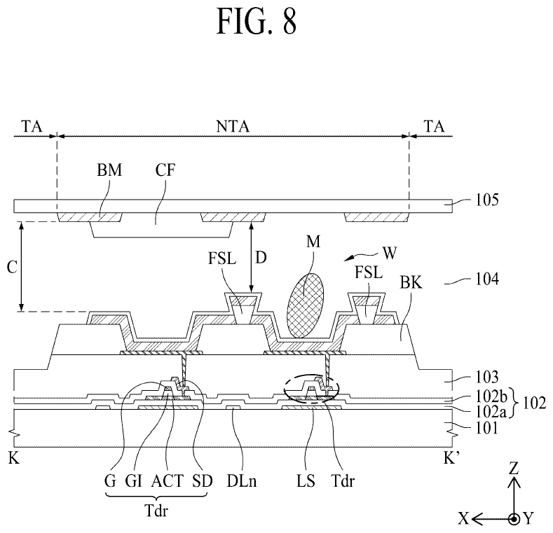

FIG. 6 is an example diagram illustrating a cross-sectional surface taken along line K-K′ illustrated in FIG. 4, FIG. 7 is an example diagram illustrating a cross-sectional surface taken along line L-L′ illustrated in FIG. 4, and FIG. 8 is another example diagram illustrating a cross-sectional surface taken along line K-K′ illustrated in FIG. 4. Particularly, FIG. 6 is an example diagram illustrating a cross-sectional surface of a color pixel (e.g., a third pixel P3) and a white pixel PW adjacent to each other, FIG. 7 is an example diagram illustrating a cross-sectional surface of two adjacent color pixels (e.g., a first color pixel P1 and a second color pixel P2), and FIG. 8 is an example diagram illustrating a cross-sectional surface in which a foreign material is included in the white pixel PW.

As described above, the light emitting display apparatus according to the present disclosure can include a substrate 101 including a display area DA and a non-display area NDA, a white pixel PW and color pixels P provided in the display area DA, and a fluorine-based protective layer FSL surrounding the outside of the white pixel PW.

For example, referring to FIGS. 6 and 7, a pixel driving circuit layer 102 is provided on the substrate 101, the pixel driving circuit layer 102 is covered by a planarization layer 103, anodes AN are provided on the upper end of the planarization layer 103, outsides of the anodes AN are covered by banks BK, a light emitting layer (or layers) EL is on the anodes AN and banks BK are covered by, a cathode CA is on the light emitting layers, and an encapsulation layer 104 is on the cathode CA. Color filters CF are provided in an area corresponding to the color pixels P1, P2, and P3 at the upper end of the encapsulation layer 104, a black matrix BM is provided between the color filters CF, and color filters CF and black matrixes BM are provided on the encapsulation substrate 105.

The substrate 101 can be a transparent glass substrate or a transparent plastic substrate.

A pixel driving circuit layer 102 can be provided on the substrate 101. The pixel driving circuit layer 102 can include at least two insulation layers and at least two metal layers, and the pixel driving circuit layer 102 can be provided with the transistors Tsw1, Tsw2, and Tdr described with reference to FIG. 2. In FIGS. 6 and 7, the driving transistor Tdr among the transistors Tsw1, Tsw2, and Tdr illustrated in FIG. 2 is illustrated. The light emitting display panel 100 illustrated in FIGS. 6 and 7 is provided with a color filter CF at an upper end of the cathode CA. Accordingly, light generated from the light emitting device ED can be emitted to the outside through the cathode CA and the color filter CF. Therefore, the light emission area EA can be provided with at least one of the transistors Tsw1, Tsw2, and Tdr included in the pixel driving circuit PDC. For example, as illustrated in FIGS. 6 and 7, the driving transistor Tdr can be provided in the light emission area EA. Accordingly, in the following description, in cases where the driving transistor Tdr does not need to be specifically mentioned, the driving transistor Tdr illustrated in FIGS. 6 and 7 can be referred to as a transistor.

The pixel driving circuit layer 102 can include a light blocking layer LS, a buffer 102a covering the light blocking layer LS, an active ACT provided on the buffer 102a, a gate insulation layer GI provided on the active ACT, a gate G provided on the gate insulation layer GI, a passivation layer 102b covering the gate G, and a source/drain SD provided on the passivation layer 102b. The pixel driving circuit layer 102 can further include another passivation layer covering the source/drain SD. Another passivation layer can be included in the planarization layer 103.

The light blocking layer LS can be disposed in the non-transmission area NTA. The light blocking layer LS can be disposed to overlap a transistor provided in the pixel driving circuit layer 102, and particularly, can be disposed to overlap the driving transistor Tdr.

For example, the light blocking layer LS can be disposed to overlap the active ACT of the driving transistor Tdr to block external light incident on the active ACT from the outside. The light blocking layer LS can be formed of any one of molybdenum (Mo), aluminum (Al), chromium (Cr), gold (Au), titanium (Ti), nickel (Ni), neodymium (Nd), and copper (Cu), or can be formed of an alloy thereof. The light blocking layer LS can be formed as a single layer or a multilayer.

Signal lines can be provided on the substrate 101 along with a light blocking layer LS. Signal lines can be, for example, data lines DL.

The buffer 102a, the gate insulation layer GI, and the passivation layer 102b can be insulation layers, and the light blocking layer LS, the gate G, and the source/drain SD can be metal layers.

Each of the transistors Tsw1, Tsw2, and Tdr provided in the pixel driving circuit layer 102 can be formed by an active ACT, a gate insulation layer GI, and a gate G.

The buffer 102a can be formed as a single layer, or can be formed as at least two inorganic layers. For example, the buffer 102a can be formed as a single layer by using any one of silicon oxide (SiOx), silicon nitride (SiNx), and silicon oxynitride (SiOxNy). Moreover, the buffer 102a can be formed as a multilayer by using at least two materials among silicon oxide (SiOx), silicon nitride (SiNx), and silicon oxynitride (SiOxNy).

The buffer 102a can be formed on the entire upper surface in order to block ions or impurities diffusing from the substrate 101 and to block moisture penetrating into the thin film transistor TFT or light emitting device through the substrate 101.

An active ACT can be disposed on the buffer 102a. The active ACT can be formed of a silicon-based semiconductor material or an oxide-based semiconductor material. The active ACT can include a channel area overlapping the gate G and source/drain areas provided at both ends of the channel area.

The gate insulation layer GI can be provided on the active ACT. The gate insulation layer GI can perform a function of insulating the active ACT and the gate G. The gate insulation layer GI can be formed of an inorganic insulation material. For example, the gate insulation layer GI can be formed as a single layer by using any one of silicon oxide (SiOx), silicon nitride (SiNx), and silicon oxynitride (SiOxNy). Moreover, the gate insulation layer GI can be formed as a multilayer by using at least two materials among silicon oxide (SiOx), silicon nitride (SiNx), and silicon oxynitride (SiOxNy).

As illustrated in FIG. 6, the gate insulation layer GI can be provided only in the area corresponding to the gate G on an upper end of the active ACT, or can be provided to cover the entire active ACT.

Accordingly, the gate insulation layer GI can be provided only in the non-transmission area NTA. Moreover, even when the gate insulation layer GI is provided in the transmission area TA, the gate insulation layer GI can be disposed only in a portion of the transmission area TA in order to improve the light transmittance of the transmission area TA.

A gate G can be provided on the gate insulation layer GI. The gate G can be provided to overlap the active ACT with the gate insulation layer GI interposed therebetween.

The gate G can be formed of any one of molybdenum (Mo), aluminum (Al), chromium (Cr), gold (Au), titanium (Ti), nickel (Ni), neodymium (Nd), and copper (Cu), formed of an alloy thereof, or can be formed as a single layer or multilayers.

A passivation layer 102b can be provided on the gate G and the buffer 102a. The passivation layer 102b can be provided to cover the gate G. The passivation layer 102b can perform a function of protecting the transistor. The passivation layer 102b can be formed as a single layer or as a multilayer by using at least one of silicon oxide (SiOx), silicon nitride (SiNx), and silicon oxynitride (SiOxNy).

The passivation layer 102b can be disposed in the non-transmission area NTA. Moreover, even when the passivation layer 102b is provided in the transmission area TA, the passivation layer 102b can be provided only in a portion of the transmission area TA in order to improve the light transmittance of the transmission area TA.

A source/drain SD can be disposed on the passivation layer 102b. The source/drain SD can be connected to a first or second electrode of a transistor through a transistor contact hole formed in the passivation layer 102b.

The first or second electrode of the transistor can be a source/drain area provided at both ends of a channel area of the active ACT.

For example, one source/drain SD provided on the passivation layer 102b can be connected to the first electrode of the transistor, and another source/drain SD provided on the first passivation layer 102b can be connected to the second electrode of the transistor.

The Source/drain SD can be formed of any one of molybdenum (Mo), aluminum (Al), chromium (Cr), gold (Au), titanium (Ti), nickel (Ni), neodymium (Nd), and copper (Cu), formed of an alloy thereof, or can be formed as a single layer or multilayers.

A planarization layer 103 can be provided on the pixel driving circuit layer 102. The planarization layer 103 can perform a function of covering and protecting the transistors and can perform a function of planarizing an upper end of the pixel driving circuit layer 102.

The planarization layer 103 can be formed by using at least one of organic and inorganic materials, and can be formed as a single layer or multilayers.

For example, the planarization layer 103 can be formed as a single layer or a multilayer by using at least one of a silicon oxide film (SiOx), a silicon nitride film (SiNx), and a silicon oxynitride film (SiOxNy).

A step height can be formed at the boundary between the non-transmission area NTA and the transmission area TA of the planarization layer 103. In this case, as illustrated in FIGS. 6 and 7, the height A of the planarization layer 103 provided in the transmission area TA can be smaller than the height B of the planarization layer 103 provided in the non-transmission area NTA. As the height of the planarization layer 103 is reduced, light transmittance in the transmission area TA can be improved.

The step height of the planarization layer 103 at the boundary between the transmission area TA and the non-transmission area NTA can be formed by etching the planarization layer 103 provided in the transmission area TA, or can be formed because the buffer 102a and the gate insulation layer GI are not provided at a lower end of the planarization layer 103 in the transmission area TA.

Anodes AN can be provided on the planarization layer 103. The anode AN can be disposed in the non-transmission area NTA.

The anode AN can be connected to the first or second electrode of the driving transistor Tdr through a transistor contact hole passing through the planarization layer 103.

The anode AN can be formed of any one of a metal, a metal alloy, and a combination of metal and oxide. For example, the anode AN can be formed in a multilayer structure including a transparent electrode layer formed of a transparent conductive material and a reflective electrode layer formed of an opaque conductive material with high reflection efficiency.

The transparent electrode layer of the anode AN can be formed of a material with a relatively high work function value, such as indium tin oxide (ITO) or indium zinc oxide (IZO). The reflective electrode layer of the anode AN can be formed of any one of silver (Ag), aluminum (Al), copper (Cu), molybdenum (Mo), titanium (Ti), nickel (Ni), chromium (Cr), and tungsten (W), or can be formed of an alloy thereof.

More specifically, the anode AN can be formed in a structure in which a transparent electrode layer, a reflective electrode layer, and a transparent electrode layer are sequentially stacked, or in a structure in which a transparent electrode layer and a reflective electrode layer are sequentially stacked, and can be formed in various combinations.

Banks BK can be provided outside the anodes AN. Particularly, the bank BK can be provided in the non-transmission area NTA.

For example, the bank BK can be formed of an inorganic material such as silicon oxide (SiOx), silicon nitride (SiNx), and silicon oxynitride (SiOxNy). Moreover, the bank BK can be formed of an organic material such as polyimide, acrylate, and benzocyclobutene series resin.

The bank BK covers the edges of the anode AN. Light can be output from an area (hereinafter simply referred to as an opening portion) of the anode AN which is not covered by the bank BK. Accordingly, the opening portion of the anode AN exposed by the bank BK can become the light emission area EA, and the portion where the bank BK is formed can become the non-emission area NEA.

Furthermore, each of the color pixels P1, P2, and P3 and the white pixel PW can be distinguished by the banks BK, e.g., the bank BK is positioned between each of the color pixels P1, P2, and P3 and the white pixel PW, and the transmission area TA and the non-transmission area TA can be distinguished by the banks BK, e.g., the bank BK is positioned between the transmission area TA and the non-transmission area TA.

In this case, the bank BK adjacent to the transmission area TA can include an inclined surface corresponding to the inclined surface of the planarization layer 103, as illustrated in FIGS. 6 and 7.

For example, the inclined surface of the bank BK can have the same or similar inclined angle as the inclined surface of the planarization layer 103. In this case, the inclined surface of the bank BK and the inclined surface of the planarization layer 103 can be continuous. Alternatively, the inclined surface of the bank BK can have a lower inclined angle than the inclined surface of the planarization layer 103. In this case, the inclined surface of the bank BK and the inclined surface of the planarization layer 103 can be continuous. Alternatively, the inclined surface of the bank BK can be offset from the inclined surface of the planarization layer 103, and in this case, a step-shaped structure can be formed between the bank BK and the planarization layer 103.

A fluorine-based protective layer FSL can be provided on the upper end of the bank BK surrounding the outside of the white pixel PW among the banks BK.

For example, as illustrated in FIGS. 4 to 6, a fluorine-based protective layer FSL can be provided on the banks BK surrounding the white pixel PW. Accordingly, the opening portion of the white pixel PW, e.g., the portion of the white pixel PW not covered by the bank BK, can be surrounded by the fluorine-based protective layer FSL.

In some examples, as illustrated in FIGS. 4 to 7, the fluorine-based protective layer FSL is not provided on the banks BK surrounding the color pixels P1, P2, and P3.

In this case, among the banks BK surrounding the color pixels P1, P2, and P3, the bank BK adjacent to the white pixel PW can be provided with a fluorine-based protective layer FSL. However, the fluorine-based protective layer FSL provided in the bank BK adjacent to the white pixel PW among the banks BK surrounding the color pixels P1, P2, and P3 may be adjacent to only part of the opening portion of each of the color pixels P1, P2, and P3, e.g., the portion of each of the color pixels P1, P2, and P3 not covered by the bank BK.

For example, as illustrated in FIGS. 4 and 6, a fluorine-based protective layer FSL can be provided on the bank BK provided between the third color pixel P3 and the white pixel PW. However, the fluorine-based protective layer FSL provided on the bank BK between the third color pixel P3 and the white pixel PW surrounds all four outsides, or border lines, of the white pixel PW, and surrounds only one of four outsides, or border line, of the color pixel P3.

The fluorine-based protective layer FSL can be formed in a reverse taper structure where the width W1 of the lower end, closer to substrate 101 than the upper end, is smaller than the width W2 of the upper end. Due to the reverse taper structure of the fluorine-based protective layer FSL, the light emitting layer EL formed of organic material cannot be formed continuously in the fluorine-based protective layer FSL. For example, portions ELF of the light emitting layer EL on top of the fluorine-based protective layer FSL is separated from the portions ELC and ELW of the light emitting layer EL adjacent to the portions ELF.

The fluorine-based protective layer FSL can be formed of one of various materials used in the manufacturing process of the light emitting display panel 100.

For example, the fluorine-based protective layer FSL can be formed of a fluoropolymer. In the fluoropolymer, carbon-carbon bonds are formed continuously in a chain structure, and the functional group of the fluoropolymer contains a large amount of fluorine (F).

As described above, the fluorine-based protective layer FSL contains a large amount of fluorine (F), and thus can have orthogonality. An orthogonality can be understood as a characteristic in which two objects exist independently, regardless of each other. Accordingly, fluorine-based materials can have both hydrophobic properties, which have low affinity for water, and oleophobic properties, which have low affinity for oil. Due to this orthogonality, the fluorine-based material can be separated from moisture or reject moisture.

Therefore, as described above, moisture penetration and moisture transfer between the white pixels PW and the color pixels can be prevented by the fluorine-based protective layer FSL.

A light emitting layer EL can be provided on the anode AN and the bank BK.

Accordingly, the light emitting layer EL can be provided in the non-transmission area NTA. However, the light emitting layer EL can also be provided in the transmission area TA. In FIGS. 6 and 7, a light emitting display panel 100 provided with a light emitting layer EL only in the non-transmission area NTA is illustrated.

As described above, the fluorine-based protective layer FSL can be formed in a reverse taper structure where the width of the lower end is smaller than the width of the upper end. That is, the width of the upper end of the fluorine-based protective layer FSL can be larger than the width of the lower end of the fluorine-based protective layer FSL.

Accordingly, the light emitting layer EL formed of an organic material cannot be formed continuously in the fluorine-based protective layer FSL.

Particular, the light emitting layer EL surrounded by the fluorine-based protective layer FSL and the light emitting layer EL provided outside the fluorine-based protective layer FSL can be separated by the fluorine-based protective layer FSL.

The light emitting layer EL surrounded by the fluorine-based protective layer FSL can mean the light emitting layer EL covering the anode AN provided in the white pixel PW. The light emitting layer EL provided outside the fluorine-based protective layer FSL can mean the light emitting layer EL covering the anodes AN provided in the color pixels P1, P2, and P3.

To provide an additional description, the light emitting layer EL on the anode AN provided in the white pixel PW and the light emitting layer EL on the anodes AN of the color pixels P1, P2, and P3 can be separated by the fluorine-based protective layer FSL.

Hereinafter, for convenience of description, the light emitting layer EL surrounded by the fluorine-based protective layer FSL is referred to as a white light emitting layer ELW, and the light emitting layer EL provided outside the fluorine-based protective layer FSL is referred to as a color light emitting layer ELC.

Because the white light emitting layer ELW and the color light emitting layer ELC are separated by the fluorine-based protective layer FSL, moisture penetrating into the white light emitting layer ELW cannot be transmitted to the color light emitting layer ELC, and moisture penetrating into the color light emitting layer ELC cannot be transmitted to the white light emitting layer ELW.

Therefore, degradation in quality and shortening of the lifespan of the light emitting device ED due to moisture penetration can be prevented.

Moreover, even if there is a portion where the white light emitting layer ELW and the color light emitting layer ELC are connected, because moisture cannot be transferred to the fluorine-based protective layer FSL formed of a fluorine-based material, moisture is not transferred to the white light emitting layer ELW and the color light emitting layer ELC. However, the fluorine-based protective layer (FSL) increases the gap between the white light emitting layer ELW and the color light emitting layer ELC, so the moisture penetration path can become longer. Therefore, it is difficult for moisture to be transmitted through the white light emitting layer ELW and the color light emitting layer ELC, and the period during which moisture is transmitted through the white light emitting layer ELW and the color light emitting layer ELC can also be prolonged. Accordingly, degradation in quality and shortening of the lifespan of the light emitting device ED due to moisture penetration can be prevented.

Furthermore, because the white light emitting layer ELW and the color light emitting layer ELC are separated by the fluorine-based protective layer FSL, leakage current between the white pixel PW and the color pixels P1, P2, and P3 can be prevented.

For example, leakage current between pixels is transmitted through the light emitting layer. However, as described above, because the white light emitting layer ELW and the color light emitting layer ELC are separated by the fluorine-based protective layer FSL, a leakage current generated in the white pixel PW is difficult to be transmitted to the color pixels P1, P2, and P3, and a leakage current generated in the color pixels P1, P2, and P3 is also difficult to be transmitted to the white pixel PW.

Accordingly, degradation of image quality due to leakage current can be prevented.

A cathode CA is provided on the light emitting layer EL. The cathode CA is not separated on the fluorine-based protective layer FSL.

The cathode CA can be provided only in the non-transmission area NTA, but can be provided in the entire transmission area TA or only a part of the transmission area TA. FIGS. 6 and 7 illustrate a light emitting display panel 100 provided with a cathode CA only in the non-transmission area NTA.

As described above, because the cathode CA can be provided on the light emitting display panel by a sputter process with high step coverage, the cathode CA can be formed continuously along the fluorine-based protective layer FSL with the reverse taper structure.

Accordingly, the same voltage can be supplied to all pixels P through the cathode CA.

An encapsulation layer 104 can be provided on the entire surface of the substrate 101. The encapsulation layer 104 can be provided in both the transmission area TA and the non-transmission area NTA.

For example, the encapsulation layer 104 can include lithium fluoride (LiF), and can also include inorganic materials such as silicon oxide (SiOx), silicon nitride (SiNx), and silicon oxynitride (SiOxNy). Moreover, the encapsulation layer 104 can be formed as multilayers including organic and inorganic materials.

The encapsulation layer 104 can be an adhesive material for bonding the substrate 101 and the encapsulation substrate 105 provided with the color filter CF and the black matrix BM.

Color filters CF can be provided in an area corresponding to the color pixels P1, P2, and P3 at an upper end of the encapsulation layer 104. For example, color filters CF can be provided at an upper end of the color pixels P1, P2, and P3. Particularly, the color filters CF can be provided to correspond to the anodes AN provided in the color pixels P1, P2, and P3.

For example, the first pixel P1 can be provided with a blue color filter CF, the second pixel P2 can be provided with a red color filter CF, and the third pixel P3 can be provided with a green color filter CF. Accordingly, blue light can be output from the first pixel P1, red light can be output from the second pixel P2, and green light can be output from the third pixel P3.

However, because white light is output from the white pixel PW itself, a color filter is not provided in the area corresponding to the white pixel PW at an upper end of the encapsulation layer 104. That is, there is no color filter on the white pixel PW.

A black matrix BM can be provided between the color filters CF. Color filters CF can be distinguished by the black matrix BM. The black matrix BM can be provided to face the banks BK surrounding the pixel P.

A black matrix BM can also be provided on an upper end of the fluorine-based protective layer FSL provided in the banks BK surrounding the white pixel PW. Accordingly, the black matrix BM can be provided to surround the white pixel.

Finally, an encapsulation substrate 105 can be provided on the black matrix BM and the color filter CF.

For example, the encapsulation substrate 105 can be bonded to the upper end of the black matrix BM and the color filter CF.

However, the color filters CF and the black matrix BM can be provided on the encapsulation substrate 105, and the encapsulation substrate 105 provided with the color filters CF and the black matrix BM can be bonded to the substrate 101 provided with the pixels P through the encapsulation layer 104.

Alternatively, the encapsulation substrate 105 provided with color filters CF and the black matrix BM can be bonded to the substrate 101 provided with the pixels P through an adhesive material applied on the encapsulation layer 104.

In this case, the encapsulation substrate 105 can be a transparent glass substrate or a transparent plastic substrate.

Accordingly, the encapsulation layer 104 can be provided between the anodes AN provided in the color pixels P1, P2, and P3 and the color filters CF, and the encapsulation layer 104 can be provided between the anode AN and the encapsulation substrate 105.

As described above, because the fluorine-based protective layer FSL can be formed in a reverse taper structure, the light emitting layer EL formed of an organic material can be formed continuously in the fluorine-based protective layer FSL. The fluorine-based protective layer FSL has a greater resistance characteristic than the light emitting layer EL.

Accordingly, transmission of moisture through the light emitting layer EL can be prevented, and leakage current through the light emitting layer EL can also be prevented.

Moreover, even if the light emitting layer EL is continuously formed on an upper end of the fluorine-based protective layer FSL, moisture and leakage current cannot be transmitted through the fluorine-based protective layer FSL. In this case, because the path of the light emitting layer EL becomes longer due to the fluorine-based protective layer FSL, the transfer speed of moisture and leakage current can decrease.

Accordingly, performance degradation of the pixels P can be prevented or reduced.

Moreover, as illustrated in FIG. 8, black matrices BM are provided at an upper end of the banks BK, and particularly, black matrices BM can also be provided at an upper end of the banks BK surrounding the white pixel PW.

In this case, a fluorine-based protective layer FSL can be provided on the banks BK surrounding the white pixel PW, and black matrices BM can be provided at an upper end of the fluorine-based protective layer FSL.

Accordingly, the gap D between the fluorine-based protective layer FSL and the black matrix BM is smaller than the gap C between the black matrix BM and the bank BK surrounding the color pixels P1, P2, and P3, as illustrated in FIG. 8.

Therefore, the moisture W penetrating into the encapsulation layer 104 of the transmission area TA is difficult to be transmitted to the inside of the white pixel PW through the gap D between the fluorine-based protective layer FSL and the black matrix BM. Moreover, because the fluorine-based protective layer FSL and the black matrix BM are provided between the color pixels P1, P2, and P3 and the white pixel PW, even when moisture penetrates into the encapsulation layer 104 inside the white pixel PW, it is difficult for the moisture penetrating into the encapsulation layer 104 inside the white pixel PW to be transmitted into the color pixels P1 through the narrow gap D between the fluorine-based protective layer FSL and the black matrix BM.

Furthermore, because the fluorine-based protective layer FSL and the black matrix BM are provided between the color pixels P1, P2, and P3 and the white pixel PW, it is difficult for moisture penetrating into the encapsulation layer 104 inside the color pixels P1, P2, and P3 to be transmitted to the white pixel PW through the narrow gap D between the fluorine-based protective layer FSL and the black matrix BM.

Accordingly, the problem where the light emitting devices ED provided in the pixels P are damaged by moisture can be removed or prevented.

Moreover, as described above, the white pixel PW is not provided with a color filter CF, and each of the color pixels P1, P2, and P3 are provided with a color filter CF. Accordingly, a color filter CF is provided at an upper end of the cathode CA provided in the color pixels P1, P2, and P3, and an encapsulation substrate 105 is provided at an upper end of the cathode CA provided in the white pixel PW.

In this case, the gap between an upper end of the cathode CA provided in the white pixel PW and the encapsulation substrate 105 is larger than the gap between an upper end of the cathode CA provided in the color pixels P1, P2, and P3 and the color filter CF.

Therefore, during the manufacturing process of the light emitting display panel 100, as illustrated in FIG. 8, even when a foreign material M is placed between the cathode CA provided in the white pixel PW and the encapsulation substrate 105, the probability of the foreign material M being pressed by the encapsulation substrate 105 can be reduced.

When the foreign material M is pressed by the encapsulation substrate 105, the possibility that the cathode CA and the anode AN come into contact by the foreign material M increases. Accordingly, a possibility that the white pixel PW with the foreign material M becomes a defective pixel increases.

Particularly, when the white pixel PW becomes a defective pixel, the decrease in luminance is large, so the unit pixel UP including the white pixel PW cannot be driven normally, and thus, the yield of the light emitting display panel can be reduced.

However, in the light emitting display panel 100 according to the present disclosure, because the gap between the upper end of the cathode CA provided in the white pixel PW and the encapsulation substrate 105 is larger than the gap between the upper end of the cathode CA provided in the color pixels P1, P2, and P3 and the color filter CF, even when the foreign material M is placed between the cathode CA provided in the white pixel PW and the encapsulation substrate 105, the probability that the white pixel PW become a defective pixel due to foreign material is low. Accordingly, the yield and quality of the light emitting display panel 100 can be improved.

In the light emitting display panel 100 according to the present disclosure, as described above, when the unit pixel UP includes three color pixels P1, P2, and P3 and a white pixel PW, a fluorine-based protective layer FSL is provided only on the banks BK surrounding the white pixel PW.

The reason why the fluorine-based protective layer FSL is provided only on the banks BK surrounding the white pixel PW is explained as follows.

For example, because the white pixel PW has a great influence on the luminance control of the unit pixel UP, the size of the white pixel PW can be larger than the size of each of the color pixels P1, P2, and P3. Moreover, the color pixels P1, P2, and P3 have to be provided with color filters CF, but the white pixel PW does not need to be provided with a color filter CF.

Accordingly, the height and thickness of the fluorine-based protective layer FSL provided in the bank BK surrounding the white pixel PW can be freely selected regardless of the resolution of the light emitting display panel 100. Therefore, fluorine-based protective layers FSL having various heights and thicknesses can be provided on the banks BK surrounding the white pixels PW.

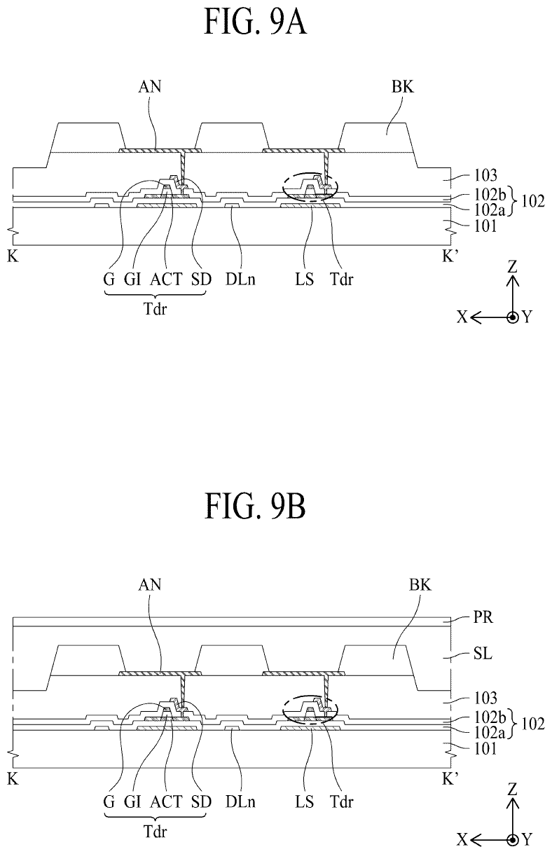

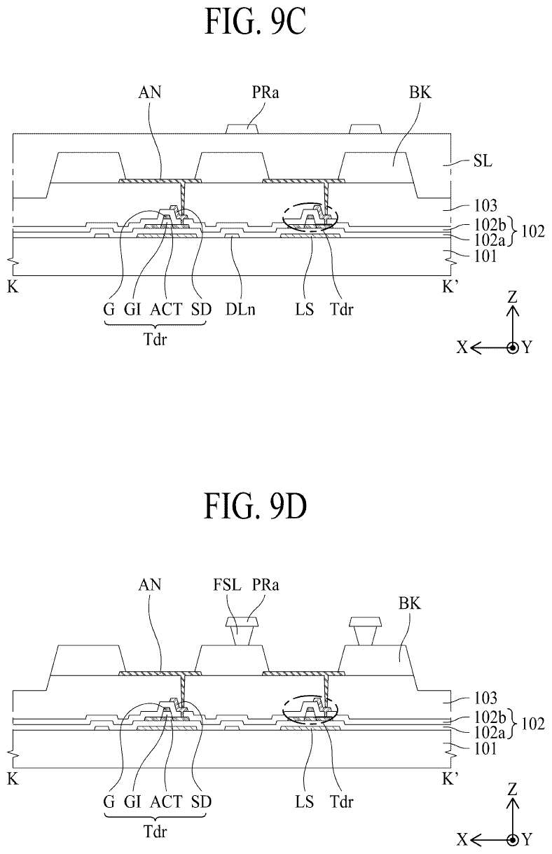

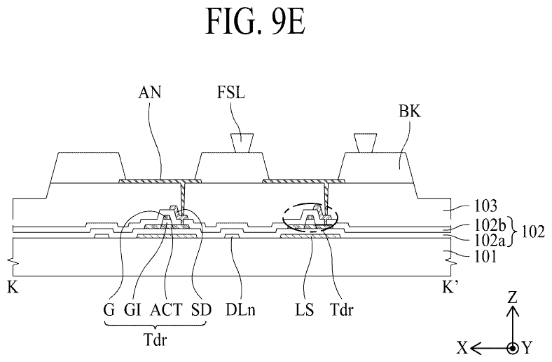

FIGS. 9A to 9E are example diagrams illustrating a method of manufacturing a light emitting display panel according to an embodiment of the present disclosure. In the following description, details which are the same as or similar to details described above with reference to FIGS. 1 to 8 are omitted or will be briefly described.

First, referring to FIG. 9A, a pixel driving circuit layer 102 including a light blocking layer LS, a buffer 102a, an active ACT, a gate insulation layer GI, a gate G, and a source/drain SD can be provided on a substrate 101.

A planarization layer 103 can be provided on the pixel driving circuit layer 102.

Anodes AN can be provided on the planarization layer 103.

Banks BK can be provided outside the anodes AN.

The substrate 101 can include a non-transmission area NTA provided with pixels P1, P2, P3, and PW and a transmission area TA.

Non-transmission or opaque elements such as transistors Tsw1, Tsw2, and Tdr and a light blocking layer LS can be provided in the pixel driving circuit layer 102 provided in the non-transmission area NTA.

A buffer 102a, a gate insulation layer GI, and a passivation layer 102b can be provided in the pixel driving circuit layer 102 provided in the transmission area TA, and a non-transmission element or an opaque element may not be disposed in the transmission area TA. Moreover, in order to improve the light transmittance of the transmission area TA, at least one of the buffer 102a, the gate insulation layer GI, and the passivation layer 102b configuring the pixel driving circuit layer 102 may not be provided in the transmission area TA.

A step height can be formed between the transmission area TA and non-transmission area NTA of the planarization layer 103 provided on the substrate 101, and an inclined surface can be formed due to the step height.

The anode AN can be provided at a position corresponding to each of the pixels P1, P2, P3, and PW.

The anode AN can be formed of a metal, a metal alloy, or a combination of metal and oxide. For example, the anode AN can be formed in a multilayer structure including a transparent electrode layer formed of a transparent conductive material and a reflective electrode layer formed of an opaque conductive material with high reflection efficiency.

The transparent electrode layer of the anode AN can be formed of a material with a relatively high work function value, such as indium tin oxide (ITO) or indium zinc oxide (IZO). The reflective electrode layer of the anode AN can be formed of any one of silver (Ag), aluminum (Al), copper (Cu), molybdenum (Mo), titanium (Ti), nickel (Ni), chromium (Cr), and tungsten (W), or can be formed of an alloy thereof.

More specifically, the anode AN can be formed in a structure in which a transparent electrode layer, a reflective electrode layer, and a transparent electrode layer are sequentially stacked, or in a structure in which a transparent electrode layer and a reflective electrode layer are sequentially stacked, and can be formed in various combinations.

Banks BK can be provided outside the anodes AN. Particularly, the bank BK can be provided in the non-transmission area NTA

For example, the bank BK can be formed of an inorganic material such as silicon oxide (SiOx), silicon nitride (SiNx), and silicon oxynitride (SiOxNy). Moreover, the bank BK can be formed of an organic material such as polyimide, acrylate, and benzocyclobutene series resin.

The banks BK cover the edges of the anode AN. Light can be output from an area (e.g., an opening portion) of the anode AN which is not covered by the bank BK. Accordingly, the opening portion of the anode AN exposed by the bank BK can become the light emission area EA, and the portion where the bank BK is formed can become the non-emission area NEA.

Furthermore, each of the color pixels P1, P2, and P3 and the white pixel PW can be distinguished by the banks BK, and the transmission area TA and the non-transmission area TA can be distinguished by the banks BK.

In this case, the bank BK adjacent to the transmission area TA can include an inclined surface corresponding to the inclined surface of the planarization layer 103, as illustrated in FIGS. 6 and 7.

For example, the inclined surface of the bank BK can have the same or similar inclined angle as the inclined surface of the planarization layer 103. In this case, the inclined surface of the bank BK and the inclined surface of the planarization layer 103 can be continuous. Alternatively, the inclined surface of the bank BK can have a lower inclined angle than the inclined surface of the planarization layer 103. In this case, the inclined surface of the bank BK and the inclined surface of the planarization layer 103 can be continuous. Alternatively, the inclined surface of the bank BK can be offset from the inclined surface of the planarization layer 103, and in this case, a step-shaped structure can be formed between the bank BK and the planarization layer 103.

As illustrated in FIG. 9B, the planarization layer 103, the banks BK, and the anodes AN are covered with a fluorine-based material SL. The fluorine-based material SL can be, for example, a fluoropolymer material. In the fluoropolymer, carbon-carbon bonds are formed continuously in a chain structure, and the functional group of the fluoropolymer includes a large amount of fluorine (F).

Fluorine-based material SL contains a large amount of fluorine (F) and thus, can have orthogonality. An orthogonality can mean a characteristic in which two objects exist independently, regardless of each other. Accordingly, fluorine-based material SL can have both hydrophobic properties, which have low affinity for water, and oleophobic properties, which have low affinity for oil. Due to this orthogonality, the fluorine-based material SL can be separated from moisture or reject moisture.

The fluorine-based material SL can be provided on the substrate 101 by using spin coating or slit coating techniques.

A photoresist layer PR can be provided on the fluorine-based material SL. The photoresist layer PR can be provided using either a positive type or a negative type photoresist material. Moreover, a Si-based surfactant can be added to the photoresist material configuring the photoresist layer PR in order to enhance interfacial adhesion properties.

Referring to FIG. 9C, after the fluorine-based material SL and the photoresist layer PR are provided, an exposure process of forming a photoresist pattern PRa exposing a portion of the surface of the fluorine-based material SL can be performed. The exposure process can be performed by exposing a portion of the photoresist layer PR to be removed to light such as ultraviolet rays (UV).

After the exposure process is performed, the exposed portion is removed using a developer, and thus a photoresist pattern PRa exposing a portion of the surface of the fluorine-based material SL can be formed. For example, the development of a photoresist pattern PRa can be performed using an alkaline chemical solution (e.g., TMAH, Tetra Methyl Ammonium Hydroxide).

Referring to FIG. 9D, after the photoresist pattern PRa is formed, a mask patterning process using the photoresist pattern PRa as a mask pattern is performed, and thus, the fluorine-based protective layers FSL can be formed. Particularly, the fluorine-based protective layers FSL can be formed by a patterning process which removes a portion of the fluorine-based material SL beneath the photoresist patterns PRa.

The patterning process for the fluorine-based protective layers FSL can be performed using a fluorine-based organic solvent. The fluorine-based organic solvent containing a large amount of fluorine (F) in the functional group penetrates into the fluorine-based material SL and selectively removes only part of the fluorine-based material SL, thereby forming the fluorine-based protective layers FSL.

In this case, due to the characteristics of the fluorine-based organic solvent, the fluorine-based material SL, and the photoresist pattern PRa, as illustrated in FIG. 9D, the fluorine-based protective layers FSL having a reverse taper structure in which a width of the lower end is smaller than a width of an upper end can be formed.

For example, the angle of the reverse taper structure can be controlled based on the type and content of the surfactant included in the photoresist layer PR. Moreover, based on the adhesion characteristics between the photoresist layer PR and the fluorine-based material SL, the angle and shape of the reverse taper structure can be controlled.

As illustrated in FIG. 9E, if the photoresist patterns PRa are removed through a cleaning process, only the fluorine-based protective layers FSL remain.

A light emitting layer EL, a cathode CA, and an encapsulation layer 104 are sequentially provided on the fluorine-based protective layers FSL.

Finally, when a color filter CF, a black matrix BM, and an encapsulation substrate 105 are sequentially provided on the encapsulation layer 104, or an encapsulation substrate 105 provided with a color filter CF and a black matrix BM is bonded to the encapsulation layer 104, manufacturing of the light emitting display panel 100 can be completed.

The features of the light emitting display apparatus according to an embodiment of the present disclosure are briefly summarized as follows.

A light emitting display apparatus according to an embodiment of the present disclosure comprises a substrate including a display area and a non-display area, a white pixel and color pixels provided in the display area, and a fluorine-based protective layer surrounding the white pixel.

The fluorine-based protective layer is provided on a bank surrounding the outside of the white pixel.

The light emitting layers are provided in the pixels, and the light emitting layer surrounded by the fluorine-based protective layer and the light emitting layer provided outside the fluorine-based protective layer are separated by the fluorine-based protective layer.

A cathode provided on the light emitting layers is not separated on the fluorine-based protective layer.

A width of an upper end of the fluorine-based protective layer is greater than a width of a lower end of the fluorine-based protective layer.

The light emitting display apparatus according to an embodiment of the present disclosure further comprises color filters provided on the color pixels.

A color filter is not provided on the white pixel.

A black matrix is provided at an upper end of the fluorine-based protective layer.

The color filters are provided on an encapsulation substrate, an encapsulation layer is provided between the color pixels and the color filters, and the encapsulation layer is provided between the white pixel and the encapsulation substrate.

A transmission area through which light transmits is provided in at least one of outsides of the white pixel.

Unit pixels are provided along an nth data line provided on the substrate, each of the unit pixels includes three color pixels and the white pixel, a first color pixel and a second color pixel among the three color pixels are arranged with the nth data line interposed therebetween, and a third color pixel among the three color pixels and the white pixel are arranged with the nth data line interposed therebetween

Among the three color pixels and the white pixel provided in the unit pixel, the fluorine-based protective layer is provided only on an outside of the white pixel.

A first transmission area through which light transmits is provided on a left side of the pixels provided on the left side of the nth data line, and a second transmission area through which light transmits is provided on a right side of the pixels provided on the right side of the nth data line.

Unit pixels are provided along the nth data line, a white pixel provided in a first unit pixel among the unit pixels is provided on the right side of the nth data line, a white pixel provided in a second unit pixel among the unit pixels is provided on the left side of the nth data line, and a white pixel provided in a third unit pixel among the unit pixels is provided on the right side of the nth data line.

According to an embodiment of the present disclosure, leakage current between pixels provided with color filters and white pixel can be prevented or reduced.

According to an embodiment of the present disclosure, moisture transfer between color pixels provided with color filters and a white pixel can be prevented or reduced.

Therefore, according to an embodiment of the present disclosure, the reliability of the light emitting display apparatus can be improved, and thus, the quality of the light emitting display apparatus can be improved.

Therefore, according to an embodiment of the present disclosure, moisture transfer between pixels provided with color filters and white pixel can be prevented or reduced, and thus, the lifespan of the light emitting display apparatus can be extended, and a low-power light emitting display apparatus can be provided.

In the description herein, example embodiments are directed to that a fluorine-based protective layer surrounds only a light-emitting layer of a white pixel, not those of the color pixels. Such example embodiments do not limit the scope of the disclosure. It is possible that a fluorine-based protective layer surrounds a light-emitting layer of a color pixel instead of or in addition to a white pixel. It is also possible that light-emitting layers of more than two pixels in a unit pixel (e.g., having 4 pixels) are surrounded by a fluorine-based protective layer or fluorine-based protective layers.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display apparatus comprising:
a substrate including a display area and a non-display area;
a white pixel and color pixels provided in the display area; and
a fluorine-based protective layer surrounding the white pixel.

2. The light emitting display apparatus of claim 1, wherein the fluorine-based protective layer is provided on a bank surrounding the white pixel.

3. The light emitting display apparatus of claim 1, wherein the white pixel includes a first light emitting layer surrounded by the fluorine-based protective layer, and
wherein the first light emitting layer and a second light emitting layer provided outside the fluorine-based protective layer are separated by the fluorine-based protective layer.

4. The light emitting display apparatus of claim 3, wherein a cathode provided on the first light emitting layer and the second light emitting layer is not separated by the fluorine-based protective layer.

5. The light emitting display apparatus of claim 1, wherein a width of an upper end of the fluorine-based protective layer is greater than a width of a lower end of the fluorine-based protective layer.

6. The light emitting display apparatus of claim 1, further comprising color filters provided on the color pixels.

7. The light emitting display apparatus of claim 6, wherein no color filter is provided on the white pixel.

8. The light emitting display apparatus of claim 6, further comprising a black matrix provided on an upper end of the fluorine-based protective layer.

9. The light emitting display apparatus of claim 6, wherein
the color filters are provided on an encapsulation substrate,
an encapsulation layer is provided between the color pixels and the color filters, and
the encapsulation layer is provided between the white pixel and the encapsulation substrate.

10. The light emitting display apparatus of claim 1, wherein a transmission area configured to allow light to transmit is provided adjacent to at least one of outsides of the white pixel.

11. The light emitting display apparatus of claim 1, wherein
unit pixels are provided along an nth data line provided on the substrate,
each of the unit pixels includes three color pixels and the white pixel,
a first color pixel and a second color pixel among the three color pixels are arranged with the nth data line interposed therebetween, and
a third color pixel among the three color pixels and the white pixel are arranged with the nth data line interposed therebetween.

12. The light emitting display apparatus of claim 11, wherein among the three color pixels and the white pixel provided in the unit pixel, the fluorine-based protective layer surrounds only the white pixel.

13. The light emitting display apparatus of claim 11, wherein a first transmission area configured to allow light to transmit is on a first side of the nth data line with two pixels of the unit pixel positioned between the first transmission area and the nth data line, and
a second transmission area configured to allow light to transmit is on a second side of the nth data line with another two pixels of the unit pixel positioned between the second transmission area and the nth data line.

14. The light emitting display apparatus of claim 13, wherein
the unit pixels includes a first unit pixel, a second unit pixel, and a third unit pixel,
a white pixel of the first unit pixel is positioned on the first side of the nth data line,
a white pixel of the second unit pixel is positioned on the second side of the nth data line, and
a white pixel of the third unit pixel is positioned on the first side of the nth data line.

15. A display device, comprising:
a substrate;
a first light emitting area on the substrate and including a first anode and a first light emitting layer on the first anode;
a second light emitting area on the substrate and including a second anode and a second light emitting layer on the second anode;
a fluorine-based structure between the first light emitting layer and the second light emitting layer, the first light emitting layer separated from the second light emitting layer by the fluorine-based structure; and
a cathode on the first light emitting layer, the second light emitting layer and the fluorine-based structure.

16. The display device of claim 15, wherein the fluorine-based structure includes a reverse taper profile having a first end and a second end opposite to the first end, the first end closer to the substrate, a first width of the first end smaller than a second width of the second end.

17. The display device of claim 15, comprising a bank structure between the first light emitting area and the second light emitting area, the fluorine-based structure on the bank structure.

18. The display device of claim 15, comprising a third light emitting layer on the fluorine-based structure, the third light emitting layer discontinuous from the first light emitting layer and from the second light emitting layer.

19. The display device of claim 15, wherein the fluorine-based structure surrounds the first light emitting layer and the fluorine-based structure does not surround the second light emitting layer.

20. The display device of claim 19, comprising a transmission area configured to allow light to transmit through, wherein the first light emitting area is adjacent to the transmission area.
